(19) United States
(12) Patent Application Publication
(10) Pub. No.: US 2026/0086125 A1
(43) Pub. Date: Mar. 26, 2026

(54) SPLIT-TYPE MEASUREMENT DEVICE

(71) Applicant: ROOTECH INC., Suwon-si (KR)

(72) Inventors: Chang-Yong JEONG, Suwon-si (KR); Young-Bok BYUN, Yongin-si (KR); Jae-Hyoung PARK, Yongin-si Gyeonggi-do (KR); Sung-Woon JO, Seoul (KR); Seong-Bong CHOI, Suwon-si (KR); Jae-Ho HWANG, Yongin-si (KR); Jung-Hun YUN, Suwon-si (KR)

(73) Assignee: ROOTECH INC., Suwon-si (KR)

(21) Appl. No.: 18/893,497

(22) Filed: Sep. 23, 2024

(51) Int. Cl. G01R 15/18; G01R 19/00

(52) U.S. Cl. CPC G01R 15/186; G01R 19/0092

(57) ABSTRACT

Proposed is a split-type measurement device including a first annular core configured to form a closed magnetic circuit around a first power line and consisting of a first upper core and a first lower core, and a second annular core configured to form a closed magnetic circuit around a second power line and consisting of a second upper core and a second lower core, wherein an upper module including an upper housing accommodating the first upper core and the second upper core and a lower module including a lower housing accommodating the first lower core and the second lower core may be combined and separated, an electric current in the first power line is measured using the first annular core, and an electric current in the second power line is measured using the second annular core.

### BACKGROUND

### Technical Field

The present disclosure relates to a split-type measurement device having a current measuring function and, more particularly, to a split-type measurement device having a removable temperature measurement module.

### Description of the Related Art

It was common to measure power in switchboards and distribution boards only at the incoming end, but recently, the demand for branch circuit measurements has been increasing for precise management of a power system.

For such measurement, a current transformer (CT) is generally installed in each branch circuit, and a signal line is connected from each CT to central measurement equipment. However, this measurement structure had limitations in increasing precision due to increased wiring complexity and difficulty in calibrating a CT module individually.

To overcome these limitations, measurement has developed in a way that a voltage measurement module that measures voltage and a current measurement module that measures current are separated, the voltage data measured by the voltage measurement module is transmitted to the current measurement module installed in each branch circuit, and each current measurement module uses the received voltage data to calculate power, etc.

As a current measurement module for measuring current, a split-type module is in great demand in the field because panel manufacturing is easy and live wire work is possible when replacing power lines. According to the present inventor's research, it was discovered that conventional split-type current measurement modules have limitations in increasing precision.

FIG. 1 is a conceptual view showing an example of a conventional split-type current measurement module being applied.

In each current measurement device 1, annular cores through which three busbars 3 connected to a molded case circuit breaker (MCCB) 2 pass, and surrounding the busbars 3 to measure an electric current for each busbar 3 are disposed.

In the split-type current measurement device 1, an upper core and a lower core are in contact to form a closed loop, and the upper core and lower core are in contact with each other in a contact area 1a. Since there is not much free space between the busbars, the cores are adjacent to each other, and in order to secure a certain level of core cross-sectional size, the core takes a long shape in the longitudinal direction of the busbar.

The above conventional configuration of the split-type current measurement device 1 was able to achieve a significant level of measurement precision. However, according to the present inventor's research, it was found that as one contact area 1a and another contact area 1a are adjacent to each other, there is a limit to the improvement in precision due to interference between adjacent cores.

In three-phase power lines connected to the same MCCB, the contact areas 1a of the cores for measurement of adjacent power lines are spaced apart by a distance d1, whereas in three-phase power lines connected to different MCCBs, the contact areas 1a of the cores for measurement of adjacent power lines are spaced apart by a distance d2, and d1 and d2 are almost identical when two MCCBs are configured adjacent to each other.

Since upper and lower cores are in contact with each other, a significant level of precision can be secured even with the split-type current measurement device. However, it was discovered that the proximity between the contact areas 1a is a problem in improving precision to achieve the highest possible precision.

### SUMMARY

Accordingly, the present disclosure has been made keeping in mind the above problems occurring in the related art, and the present disclosure is intended to provide a split-type measurement device that can overcome existing measurement accuracy limitations.

In addition, an objective of the present disclosure is to provide a split-type measurement device with improved measurement precision.

In addition, an objective of the present disclosure is to provide a temperature measurement module and a split-type measurement device, which allow easier temperature measurement.

In order to achieve the above objective, according to an aspect of the present disclosure, there is provided a split-type measurement device including: a first annular core configured to form a closed magnetic circuit around a first power line and consisting of a first upper core and a first lower core; and a second annular core configured to form a closed magnetic circuit around a second power line and consisting of a second upper core and a second lower core, wherein an upper module including an upper housing accommodating the first upper core and the second upper core and a lower module including a lower housing accommodating the first lower core and the second lower core may be combined and separated, an electric current in the first power line may be measured using the first annular core, whereas an electric current in the second power line may be measured using the second annular core, and the first annular core and the second annular core may be arranged to be spaced apart from each other in an extension direction, which is a direction in which the first power line and the second power line extend.

A pair of first contact areas where the first upper core and the first lower core contact each other and a pair of second contact areas where the second upper core and the second lower core contact each other core may be arranged to be spaced apart from each other in an extension direction, which is a direction in which the first power line and the second power line extend.

In the split-type measurement device, the pair of first contact areas and the pair of second contact areas may be square-shaped areas, and a width in a transverse direction perpendicular to the extension direction may be greater than 0.5 times but less than 2 times a width in the extension direction.

In the split-type measurement device, the width in the transverse direction may be equal to the width in the extension direction.

In the split-type measurement device, a separation distance (L) between the pair of first contact areas and the pair of second contact areas in the extension direction may be greater than 20 mm.

In the split-type measurement device, a main body in which the upper module and the lower module are combined may have a shape of [symbol] or [symbol] having protruding parts on opposite sides when viewed from above.

In the split-type measurement device, in a main body in which the upper module and the lower module are combined, a protruding portion and a depressed portion may be formed in succession on a first side, and a protruding portion and a depressed portion may be formed in succession on a second side opposite the first side, wherein the depressed portion of the second side may be formed on an opposite side of the protruding portion of the first side, and the protruding portion of the second side may be formed on an opposite side of the depressed portion of the first side.

In the split-type measurement device, when two main bodies are placed adjacent to each other, a protruding portion of a second main body may be accommodated in a depressed portion of a first main body, and a protruding portion of the first main body may be accommodated in a depressed portion of the second main body.

In the split-type measurement device, for a three-phase four-wire power lines, the first main body may perform current measurements for two of the four power lines, and the second main body may perform current measurements for the remaining two of the four power lines.

In the split-type measurement device, a part of the first annular core may be positioned inside the protruding portion of the first side, and a part of the second annular core may be positioned inside the protruding portion of the second side.

In the split-type measurement device, in two pairs of single-phase power lines, by performing current measurements for two neighboring power lines using the first annular core and the second annular core, current measurements for two pairs of single-phase power lines may be performed simultaneously.

In the split-type measurement device, in a three-phase three-wire power lines, by performing current measurements for two neighboring power lines using the first annular core and the second annular core, current measurements for the three-phase three-wire power lines may be performed.

In the split-type measurement device, at a top of the lower housing, a first cylindrical wall standing upright in a shape of a square cylinder surrounding a 1-1 contact area which is close to a side among the first contact areas, and a second cylindrical wall standing upright in a shape of a square cylinder surrounding a 2-1 contact area which is close to a side among the second contact areas may be provided.

In the split-type measurement device, at a top of the lower housing, a third cylindrical wall standing upright in a shape of a square cylinder surrounding a 1-2 contact area which is in a center among the first contact areas and a 2-2 contact area which is in a center among the second contact areas may be provided.

In the split-type measurement device, at a bottom of the upper housing, an insertion part inserted and aligned with the third cylindrical wall and installed to stand downwardly may be provided, wherein inside the third cylindrical wall, a key piece may be provided to stand in a direction perpendicular to the third cylindrical wall, and the key piece may be inserted into a key groove of the insertion part to help match the upper module and the lower module.

In the split-type measurement device, in the upper housing and the lower housing combined with each other, a first line through hole through which the first power line passes and a second line through hole through which the second power line passes may be formed, and the upper module may further include:

a first temperature sensor stored in the upper housing and disposed above the first line through hole to sense the temperature of the first power line; and a second temperature sensor stored in the upper housing and disposed above the second line through hole to sense the temperature of the second power line.

The split-type measurement device may further include: a first temperature measurement module configured to be detachably coupled to the upper module on a first side of the upper module, and to sense the temperature of an adjacent power line that does not penetrate the main body; and a second temperature measurement module configured to be detachably coupled to the upper module on a second side opposite to the first side of the upper module, and to sense the temperature of an adjacent power line that does not penetrate the main body.

In the split-type measurement device, each of the first temperature measurement module and the second temperature measurement module may include: a module connection pin configured to be connected to a main body connection pin of the upper module; a temperature sensor configured to move a position thereof by sliding in a transverse direction and to sense the temperature of a power line downward; and an FPCB interposed between the temperature sensor and the module connection pin and configured to form a path for electrical signals.

The split-type measurement device may further include: a sliding module equipped with the temperature sensor and having a window or a lens on a bottom thereof that allows passage of sensing light; and a guide case configured to guide a sliding of the sliding module.

In the split-type measurement device, the guide case may be configured with a flange that extends in the vertical direction around the module connection pin, and a trench that matches the flange may be formed in the upper housing around the main body connection pin, and thus by sliding the flange from the bottom to the top of the trench and fitting the flange into the trench, the first temperature measurement module and the second temperature measurement module may be mounted.

The split-type measurement device may further include: a plurality of micro grooves formed in the transverse direction on an upper surface of the sliding module; and a cantilever constructed on an upper part of the guide case and extending in the transverse direction, and having a protrusion formed at a lower part of a front end thereof to be seated in one of the micro grooves.

In the split-type measurement device, on the upper surface of the sliding module, a plurality of characters indicating the specifications of the MCCB may be printed or engraved next to the plurality of micro grooves, and on the upper part of the guide case, a confirmation window through which one of the characters is exposed may be formed.

According to a split-type measurement device of the present disclosure, it is easy to arrange contact areas of cores so that the contact areas are sufficiently spaced apart from each other and are not adjacent to each other, which can minimize interference between contact areas and interference with power lines, thereby increasing measurement precision significantly compared to conventional split-type measurement devices. Therefore, it is possible to overcome the limitations in measurement precision of conventional split-type measurement devices.

According to a split-type measurement device of the present disclosure, it is possible to make a contact surface of an upper core and a lower core square or in a shape with a small difference in horizontal and vertical size, which can further increase measurement precision compared to conventional split-type measurement devices.

According to a split-type measurement device of the present disclosure, cylindrical walls formed on both sides of a power line secure clearance between the power line and a contact area (core) and enable complete insulation, thereby maximizing electrical safety.

According to a split-type measurement device of the present disclosure, protrusions and depressions are formed on the sides of the split-type measurement device in the transverse direction, and each protrusion is configured to match the depression on the opposite side, so that multiple split-type measurement devices can be easily applied in close contact in the transverse direction.

According to a split-type measurement device and a temperature measurement module of the present disclosure, since a user can configure the temperature measurement module in a detachable manner, the temperature can be sensed even for an adjacent power line that does not penetrate a main body, and the same main body can be applied even in applications where the main body is placed one after another by removing the temperature measuring module.

According to a split-type measurement device and a temperature measurement module of the present disclosure, since the position of a temperature sensor extending from a main body can be adjusted, the temperature of an external power line can be sensed by adapting to various standards of power line spacing (MCCB of various standards).

According to a split-type measurement device and a temperature measurement module of the present disclosure, it is easy to set the position of a temperature sensor according to the specifications of an MCCB and ensure that the temperature sensor is located exactly above a power line.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a conceptual view showing an example of a conventional split-type current measurement module being applied;

FIGS. 2 and 3 are external perspective views showing a split-type measurement device according to an embodiment of the present disclosure;

FIGS. 4 and 5 are external perspective views showing an upper module, a lower module, and a temperature measurement module separated from each other;

FIGS. 6 and 7 are exploded perspective views showing a temperature measurement module and an upper module in a split-type measurement device according to an embodiment of the present disclosure;

FIGS. 8 and 9 are exploded perspective views showing a lower module in a split-type measuring device according to an embodiment of the present disclosure;

FIGS. 10A and 10B are, respectively, is a perspective view showing a temperature measurement module according to an embodiment of the present disclosure;

FIGS. 11 and 12 are perspective views showing a disassembled temperature measurement module according to an embodiment of the present disclosure;

FIG. 13 is a view schematically showing a split-type measurement device according to an embodiment of the present disclosure;

FIGS. 14A and 14B are, respectively, a view schematically showing a state in which a split-type measurement device according to an embodiment of the present disclosure is mounted on three-phase, three-wire power lines;

FIG. 15A is a view schematically showing a state in which a split-type measurement device according to an embodiment of the present disclosure is mounted on two single-phase power lines, and FIG. 15B is a view schematically showing a state in which a split-type measurement device according to an embodiment of the present disclosure is mounted on a three-phase, four-wire power line;

FIGS. 16A to 16C are, respectively, a view schematically showing a state in which a temperature measurement module is mounted on a main body of a split-type measurement device according to an embodiment of the present disclosure, with FIGS. 16A and 16B showing different examples of mounting the temperature measurement module on a three-phase, three-wire power line, and FIG. 16C showing an example of mounting the temperature measurement module on two pairs of single-phase power lines;

FIGS. 17A and 17B are, respectively, a diagram showing a simulation situation;

FIGS. 18 and 19 are a visual representation of the magnetic flux density (peak value) in adjacent cores (CTs), with FIG. 18 being according to the arrangement (separation in transverse direction) of FIG. 17A, and FIG. 19 being according to the arrangement (separation in extension direction) of FIG. 17B;

FIGS. 20 and 21 are graphs showing the crosstalk ratio according to a separation distance between cores (CTs), with FIG. 20 being according to the arrangement (separation in transverse direction) of FIG. 17A, and FIG. 21 being according to the arrangement (separation in extension direction) of FIG. 17B;

FIGS. 22A to 22D are, respectively, a diagram showing a simulation situation performed to determine a separation distance with little influence of crosstalk; and

FIGS. 23A and 23B are, respectively, a table showing the output voltage and crosstalk ratio.

### DETAILED DESCRIPTION

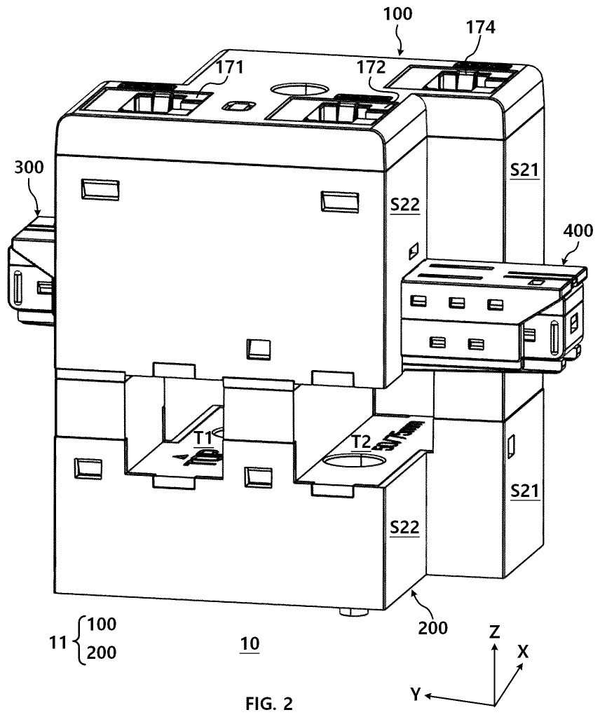

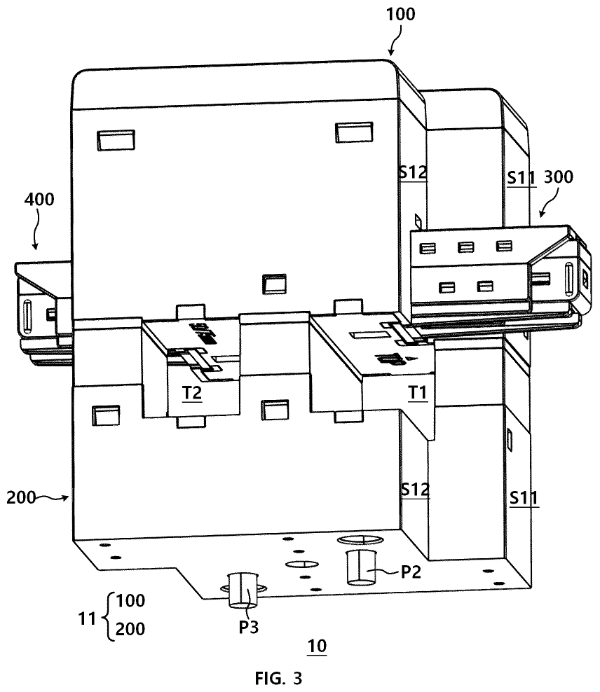

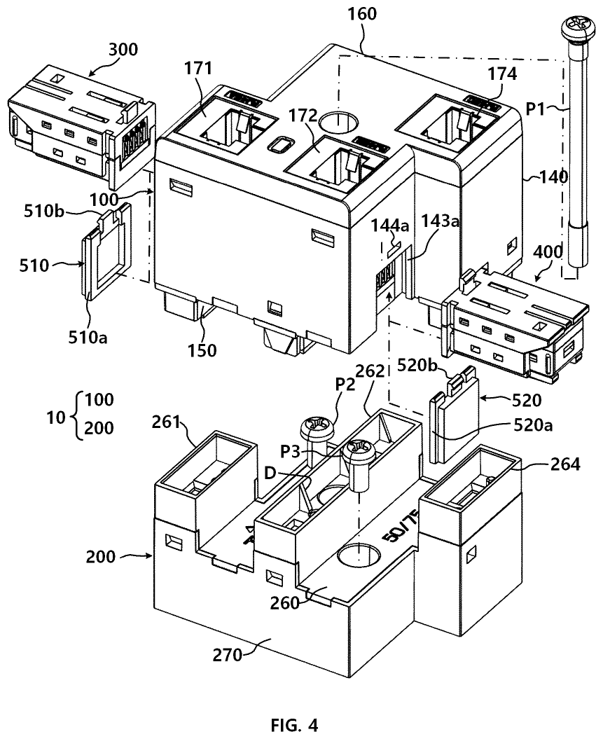

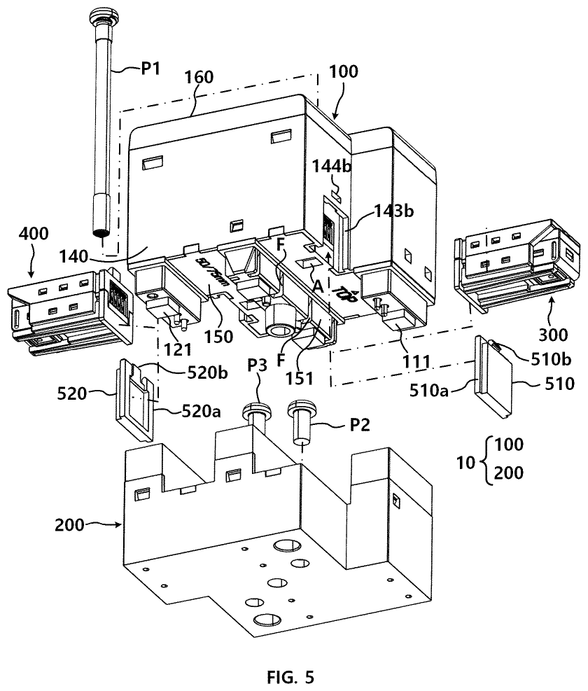

FIGS. 2 and 3 are external perspective views showing a split-type measurement device according to an embodiment of the present disclosure. FIGS. 4 and 5 are external perspective views showing an upper module, a lower module, and a temperature measurement module separated from each other.

A split-type measurement device 10 according to an embodiment of the present disclosure is installed for each branch circuit in a distribution board or a switchboard, and a central measurement device and each split-type measurement device 10 are connected by a data communication line. The split-type measurement device 10 receives voltage data from the central measurement device, calculates a power value using the electric current measured by the split-type measurement device 10, and transmits the calculated power value to the central measurement device.

The split-type measurement device 10 according to an embodiment of the present disclosure includes an upper module 100, a lower module 200, a first temperature measurement module 300, and a second temperature measurement module 400. As the name suggests, the split-type measurement device 10 according to an embodiment of the present disclosure allows a user to separate the upper module 100 and the lower module 200 from each other and combine the upper module 100 and the lower module 200 with each other. The upper module 100 and lower module 200 constitute a main body 11 of the split-type measurement device.

The interconnected upper module 100 and lower module 200 have a first line through hole T1 through which a power line such as a busbar or an electrical wire passes, and a second line through hole T2 through which another power line passes. In a housing, the first line through hole T1 through which a first power line passes and the second line through hole T2 through which a second power line passes are formed.

The split-type measurement device 10 according to an embodiment of the present disclosure has two power lines (busbar or wire) passing therethrough, and the upper module 100 and the lower module 200 may be installed, for example, by mounting the lower module 200 on a panel of a distribution board or a switchboard using bolts P2 and P3 or pieces, placing the power lines in the areas that will be the line through holes T1 and T2, and then coupling the upper module 100 to the lower module 200 using the bolt P1.

The line through holes T1 and T2 are formed in the main body 11 in accordance with the direction (X direction, hereinafter also referred to as the “extension direction”) in which the power line extends and consist of an empty space approximately in the shape of a square pillar in the extension direction. Although not exposed on the exterior of the combined main body, as described later, a first annular core is disposed around the first line through hole T1, and a second annular core is disposed around the second line through hole T2. The main body 11 includes the first annular core, the second annular core, and the housing.

Uniquely, in the main body 11, there is a step difference on the side in the direction (Y direction) that is perpendicular to the extension direction (X direction) and that crosses the two power lines. A first side is composed of a 1-1 side S11 and a 1-2 side S12, and there is a step difference between the 1-1 side S11 and the 1-2 side S12. A second side is composed of a 2-1 side S21 and a 2-2 side S22, and there is a step difference between the 2-1 side S21 and the 2-2 side S22.

The 1-2 side S12 is located in a more depressed position than the 1-1 side S11 so that a depressed portion is formed next to the 1-2 side S12. The 2-2 side S22 is located in a more depressed position than the 2-1 side S21 so that a depressed portion is formed next to the 2-2 side S22.

When viewed upside down, the 1-1 side S11 is in a position that protrudes more than the 1-2 side S12, so that the main body has a protruding portion reaching the 1-1 side S11, and the 2-1 side S21 is in a position that protrudes more than the 2-2 side S22, so that the main body has a protruding portion reaching the 2-1 side S21. The 1-2 side S12 meets the first line through hole T1 and is cut off at the middle part thereof, and the 2-2 side S22 meets the second line through hole T2 and is cut off at the middle part thereof.

On the first and second sides, the depressed portions and protruding portions extend with the same profile in the vertical direction (Z direction) that is perpendicular to the extension direction.

Connectors 171 and 172 for supplying power and transmitting communication signals are exposed on the upper surface of the upper module 100, the first temperature measurement module 300 may be installed on the first side (specifically, the 1-2 side S12), and the second temperature measurement module 400 may be installed on the second side (specifically, the 2-2 side S22).

The upper module 100 and the lower module 200 are essentially configured, but the first temperature measurement module 300 and the second temperature measurement module 400 may be configured as both, only one, or not at all.

The temperature measurement modules 300 and 400 be used to measure the temperature of adjacent power lines that do not penetrate the main body 11. When the temperature measurement module is used, the temperature measurement module is installed by sliding the temperature measurement module from the bottom to the top of the main body (upper module) and then fixed.

When the first temperature measurement module 300 is not configured, a first cover 510 is slidably inserted into the upper module 100 to block the part where the first temperature measurement module 300 is coupled, and when the second temperature measurement module 400 is not configured, a second cover 520 is slidably inserted into the upper module 100 to block the part where the second temperature measurement module 400 is coupled.

The first temperature measurement module 300 may be detachably coupled to the upper module 100 on the first side of the main body 10 (specifically, the upper module 100), and senses the temperature of an adjacent power line that does not penetrate the main body. The second temperature measurement module 400 may be detachably coupled to the upper module 100 on the second side opposite to the first side of the main body 10 (specifically, the upper module 100), and senses the temperature of another adjacent power line that does not penetrate the main body.

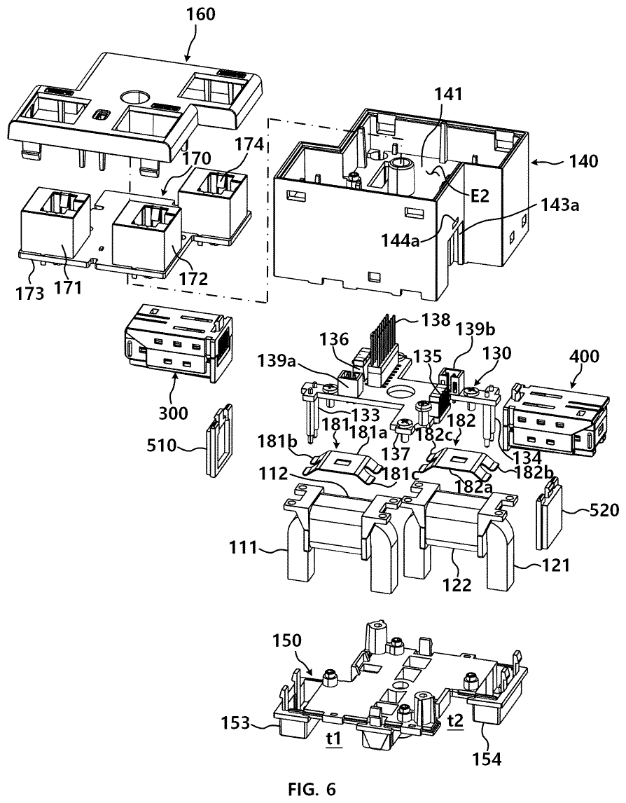

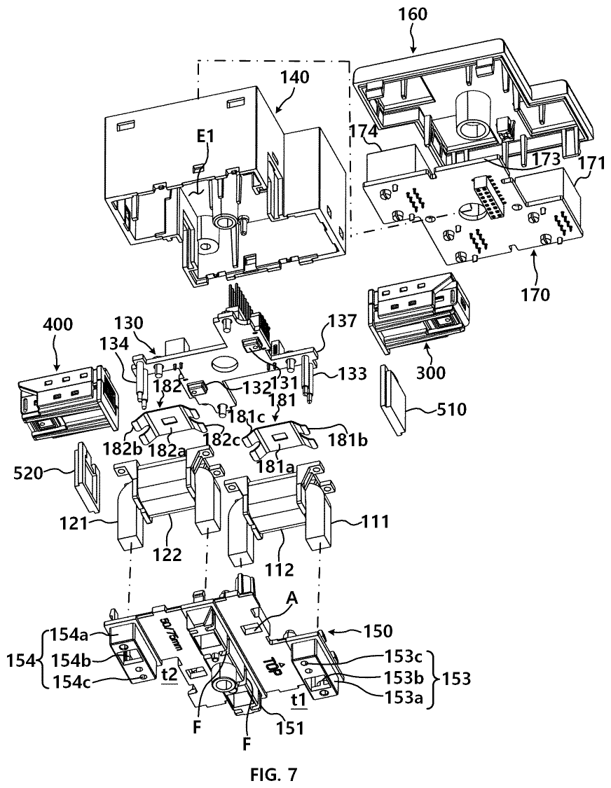

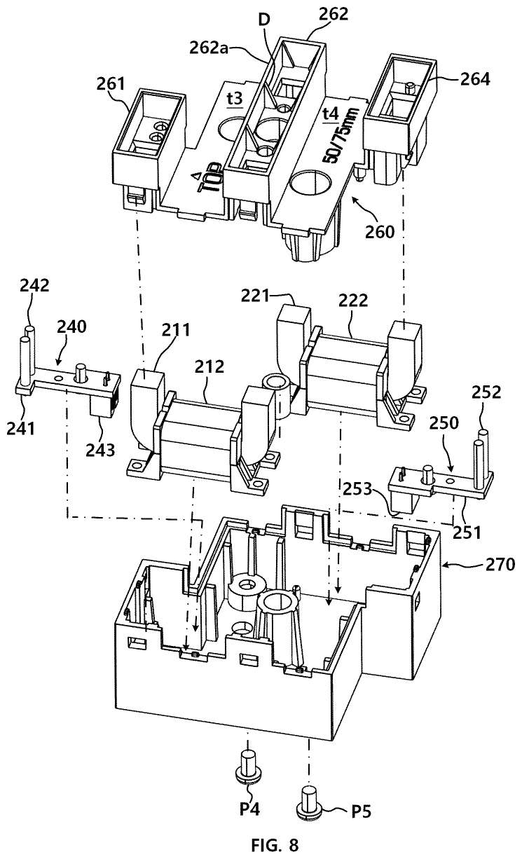

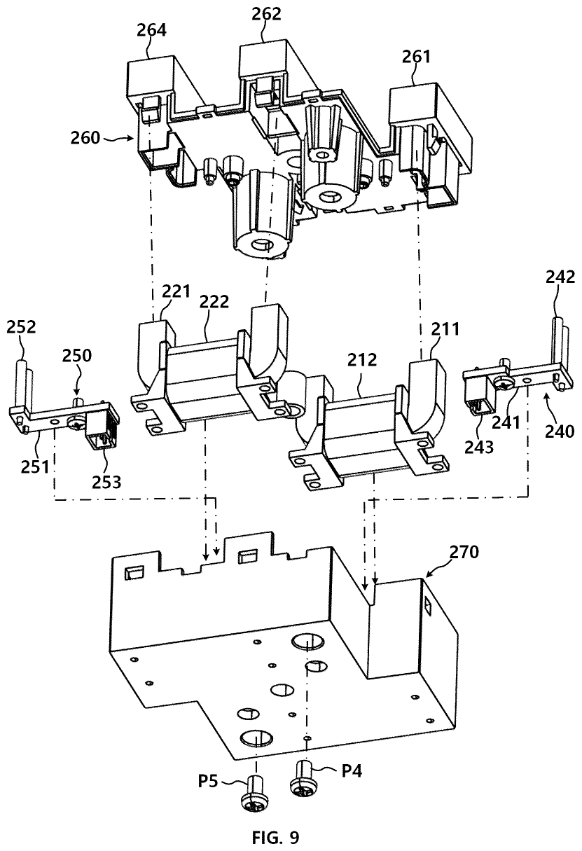

FIGS. 6 and 7 are exploded perspective views showing the temperature measurement module and the upper module in the split-type measurement device according to an embodiment of the present disclosure. FIGS. 8 and 9 are exploded perspective views showing the lower module in the split-type measuring device according to an embodiment of the present disclosure.

The upper module 100 includes a first upper core 111, a second upper core 121, a first upper bobbin 112, a second upper bobbin 122, an upper PCB assembly 130, a first upper housing 140, a second upper housing 150, a first leaf spring 181, a second leaf spring 182, a top cover 160, and a main PCB assembly 170.

The lower module 200 includes a first lower core 211, a second lower core 221, a first lower bobbin 212, a second lower bobbin 222, a first lower PCB assembly 240, a second lower PCB assembly 250, a first lower housing 260, and a second lower housing 270.

The housing of the main body 11 includes the first upper housing 140, the second upper housing 150, the first lower housing 260, and the second lower housing 270. An upper housing accommodates the first upper core and the second upper core and includes the first upper housing 140 and the second upper housing 150. A lower housing accommodates the first lower core and the second lower core and includes the first lower housing 260 and the second lower housing 270.

The first upper core 111 and the first lower core 211, which are in contact with each other, constitute a first annular core of a ring shape, and the first annular core forms a closed magnetic circuit around the first power line that will pass through the first line through hole T1. The first upper core 111 and the first lower core 211 have a square cross-section and the square cross-section is extended to form a closed loop. The first annular core is aligned so that a central penetration portion thereof eventually coincides with the first line through hole T1.

When the upper module 100 and the lower module 200 are combined, the first upper core 111 and the first lower core 211 contact each other, forming a pair of square first contact areas.

One of the first contact areas is an area where one end of the first upper core 111 and one end of the first lower core 211 contact, and the other one of the first contact areas is an area where the other end of the first upper core 111 and the other end of the first lower core 211 contact.

The first upper bobbin 112 surrounds the first upper core at the upper part of the first upper core 111 and provides a frame on which a first upper coil (not shown) can be wound, and provides insulation from the first upper coil. The first lower bobbin 212 surrounds the first lower core at the lower part of the first lower core 211 and provides a frame on which a first lower coil (not shown) can be wound, and provides insulation from the first lower coil.

The second upper core 121 and the second lower core 221, which are in contact with each other, constitute a second annular core of a ring shape, and the second annular core forms a closed magnetic circuit around the second power line that will pass through the second line through hole T2. The second upper core 121 and the second lower core 221 have a square cross-section and the square cross-section is extended to form a closed loop. The second annular core is aligned so that a central penetration portion thereof eventually coincides with the second line through hole T2.

When the upper module 100 and the lower module 200 are combined, the second upper core 121 and the second lower core 221 contact each other, forming a pair of square second contact areas.

One of the second contact areas is an area where one end of the second upper core 121 and one end of the second lower core 221 contact, and the other one of the second contact areas is an area where the other end of the second upper core 121 and the other end of the second lower core 221 contact.

The second upper bobbin 122 surrounds the second upper core at the upper part of the second upper core 121 and provides a frame on which a second upper coil (not shown) can be wound, and provides insulation from the second upper coil. The second lower bobbin 222 surrounds the second lower core at the lower part of the second lower core 221 and provides a frame on which a second lower coil (not shown) can be wound, and provides insulation from the second lower coil.

The first leaf spring 181 has wing parts 181b and 181c that descend downward on opposite sides of a plate-shaped central part 181a, is located above the first upper bobbin 112, and presses the first upper bobbin 112 downward, thereby promoting close contact between the first upper core and the first lower core. The second leaf spring 182 has wing parts 182b and 182c that descend downward on opposite sides of a plate-shaped central part 182a, is located above the second upper bobbin 122 and presses the second upper bobbin 122 downward, thereby promoting close contact between the second upper core and the second lower core.

The upper housing is composed of the first upper housing 140 and the second upper housing 150 to accommodate various parts constituting the upper module 100. In the internal space created due to the coupling of the first upper housing 140 and the second upper housing 150, the first upper core 111, the second upper core 121, first upper bobbin 112, the second upper bobbin 122, the first leaf spring 181, the second leaf spring 182, and the upper PCB assembly 130 are accommodated.

The first upper housing 140 has an outline of the shape of [symbol] or [symbol] , extends up and down (in the Z direction), and provides a space therein. The second upper housing 150 covers the bottom of the first upper housing 140, but has openings through which the lower ends of the first upper core 111 and the second upper core 121, and the lower ends of a first upper pogo pin 133 and a second upper pogo pin 134 extending downward from the upper PCB assembly 130 are slightly exposed. The second upper housing 150 has an inverted U-shaped first upper trench t1 and a second upper trench t2 to form approximately half of the first line through hole T1 and the second line through hole T2.

A first upper plug part 153 and a second upper plug part 154 extending downward are formed in the second upper housing 150.

The first upper plug part 153 includes: a first plug block 153a whose outline is roughly in the shape of a short square pillar; a first core through hole 153b which is a space of a square pillar formed in the first plug block 153a, and through which the first upper core 111 passes; and a first pogo pin through hole 153c which is a cylindrical space formed in the first plug block 153a, and through which the first upper pogo pin 133 passes.

The second upper plug part 154 includes: a second plug block 154a whose outline is roughly in the shape of a short square pillar; a second core through hole 154b which is a space of a square pillar formed in the second plug block 154a, and through which the second upper core 121 passes; and a second pogo pin through hole 154c which is a cylindrical space formed in the second plug block 154a, and through which the second upper pogo pin 134 passes.

The first upper housing 140 has a first upper space E1 and a second upper space E2 centered on a housing partition wall 141. The first upper space E1 accommodates the first upper core 111, the second upper core 121, the first upper bobbin 112, the second upper bobbin 122, and the upper PCB assembly 130, whereas the second upper space E2 accommodates the upper PCB assembly 130.

The upper PCB assembly 130 is accommodated in the first upper space E1, and includes a PCB board 137, a first temperature sensor 131, a second temperature sensor 132, the upper pogo pins 133 and 134, main body connection pins 135 and 136, a first upper socket 139a, a second upper socket 139b, and a connection pin 138.

The upper pogo pins 133 and 134 are mounted from the bottom of the PCB board 137 and are used to transmit signals to/from the first lower PCB assembly 240 and the second lower PCB assembly 250, respectively. The main body connection pins 135 and 136 are mounted on the upper surface of the PCB board 137 and are used to transmit signals to/from the first temperature measurement module 300 and the second temperature measurement module 400. Both ends of the first upper coil are connected to the first upper socket 139a, and both ends of the second upper coil are connected to the second upper socket 139b. The connection pin 138 is for transmitting signals to/from the main PCB assembly 170.

The first temperature sensor 131 is stored in the housing (upper housing) and is disposed above (or below) the first line through hole T1 to sense the temperature of the first power line. The first temperature sensor 131 is mounted on the lower surface of the PCB board 137 and allows sensing light to pass through a window A provided in the second upper housing 150.

The first temperature sensor 131 measures the temperature of the first power line passing through the first line through hole T1 above the first upper trench t1.

The second temperature sensor 132 is stored in the housing (upper housing) and is disposed above (or below) the second line through hole T2 to sense the temperature of the second power line. The second temperature sensor 132 is mounted on the lower surface of the PCB board 137 and allows sensing light to pass through the window provided in the second upper housing 150. The second temperature sensor 132 measures the temperature of the second power line passing through the second line through hole T2 above the second upper trench t2.

A lens may be provided in the window A or between the temperature sensor and the window A. The lens may be used to focus the sensing light, narrow the angle (range) of the temperature sensor, and accurately sense only the power line. A filter may be provided in the window A or between the temperature sensor and the window A. The filter may be used to narrow the angle (range) of the temperature sensor by allowing some of the sensing light (e.g., the central portion) to pass through, allowing only the power line to be sensed accurately.

The temperature sensors 131 and 132 are a non-contact temperature sensor, for example, an infrared temperature sensor.

The main PCB assembly 170 is accommodated in the second upper space E2, and includes a PCB 173, and the first connector 171, the second connector 172, and a third connector 174. The upper cover 160 covers the exposed second upper space E2 of the first upper housing 140.

The first connector 171 and the second connector 172 may be used to supply power and transmit communication signals in a daisy chain topology. The third connector 174 may be used to connect an additional sensor module, for example, to connect a ZCT module to the split-type measurement device (main body).

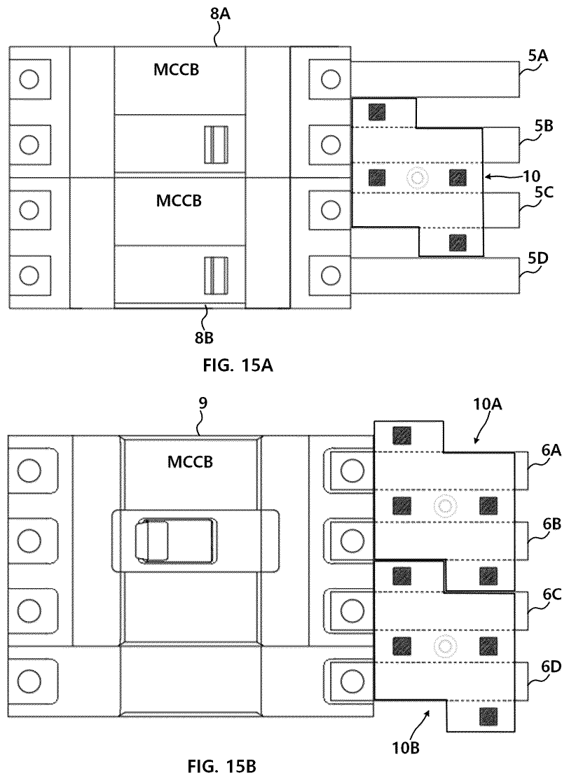

In addition, the split-type measurement devices may be divided into two types, and may be used by dividing two types of the split-type measurement into devices main split-type measurement devices and sub split-type measurement devices. The main split-type measurement devices are connected in the daisy chain topology using the first connector 171 and the second connector 172, and the sub split-type measurement devices may be connected to the main split-type measurement devices using the third connector 174. For example, when measuring a three-phase, four-wire power line as shown in FIG. 15B, one of the two split-type measurement devices may be used as a main split-type measurement device and the other as a sub split-type measurement device.

The lower housing is composed of the first lower housing 260 and the second lower housing 270 to accommodate components that constitute the lower module. To be specific, the lower housing accommodates the first lower core 211, the second lower core 221, the first lower bobbin 212, the second lower bobbin 222, the first lower PCB assembly 240, and the second lower PCB assembly 250.

The second lower housing 270 has an outline of the shape of [symbol] or [symbol] , extends up and down (in the Z direction), and provides a space therein. The first lower housing 260 blocks the upper part of the second lower housing 270, but exposes the upper parts of the first lower core 211 and the second lower core 221, and allows the upper parts of the first lower pogo pin 242 and the second lower pogo pin 252 to pass through and be exposed. In the first lower housing 260, a first lower trench t3 and a second lower trench t4 are provided, each having an approximately U-shape, to form approximately half of the first line through hole T1 and the second line through hole T2. In the upper housing and the lower housing which are joined to each other, the first line through hole T1 through which the first power line passes and the second line through hole through which the second power line passes are formed.

The first lower PCB assembly 240 includes a PCB 241, a first lower socket 243 to which both ends of a first lower coil (not shown) are connected, and a first lower pogo pin 242 in contact with the first upper pogo pin. The second lower PCB assembly 250 includes a PCB 251, a second lower socket 253 to which both ends of a second lower coil (not shown) are connected, and a second lower pogo pin 252 in contact with the second upper pogo pin.

A third cylindrical wall 262 is constructed in a rectangular shape on the lower housing (specifically, the first lower housing 260) by surrounding a 1-2 contact area, which is the contact area in the center among the pair of first contact areas and a 2-2 contact area, which is the contact area in the center among the pair of second contact areas.

Inside the third cylindrical wall 262, a key piece D is provided that is installed perpendicularly between the third cylindrical wall and the floor and has a shape roughly like a triangular plate. The key piece D is inserted into a key groove F of an insertion part 151 to help alignment between the upper module 100 and the lower module 200.

In addition, a first cylindrical wall 261 is constructed in a rectangular shape surrounding a 1-1 contact area which is close to the side among the pair of first contact areas, and a second cylindrical wall 264 is constructed in a rectangular shape surrounding a 2-1 contact area which is close to the side among the pair of second contact areas.

Inside the first cylindrical wall 261, an end of the first upper core 111 and the first upper plug 153 are received from the open upper side of the first cylindrical wall 261, and inside the second cylindrical wall 264, an end of the second upper core 121 and the second upper plug 154 are received from the open upper side of the second cylindrical wall 264.

The first cylindrical wall 261 completely surrounds the first contact area (specifically, the 1-1 contact area) to ensure complete insulation and clearance between the contact area and the first power line, and further, provides complete insulation and clearance between the contact area and other adjacent power lines that do not penetrate the split-type measurement device. The second cylindrical wall 264 surrounds the second contact area (specifically, the 2-1 contact area) to ensure complete insulation and clearance between the contact area and the second power line, and further, provides complete insulation and clearance between the contact area and other adjacent power lines that do not penetrate the split-type measurement device.

The third cylindrical wall 262 completely surrounds the 1-2 contact area and the 2-2 contact area to ensure complete insulation and clearance between the contact areas and the first power line and the second power line.

According to the split-type measurement device of the present disclosure, the cylindrical walls provided on opposite sides and in the center of the power lines secure clearance between the power lines and the contact areas (core) and provide complete insulation, thereby maximizing electrical safety.

The bottom of the upper housing is configured with the insertion part 151 that is inserted and aligned with the third cylindrical wall. The insertion part 151 is a plug shape that is installed downward between the first upper trench t1 and the second upper trench t2, and allows penetration of the first upper core and the second upper core. On the side of the insertion part 151, the key groove F is provided into which the key piece D is inserted. The horizontal depth of the key groove F becomes narrower from bottom to top, corresponding to the narrowing of the triangular plate-shaped key piece D from bottom to top.

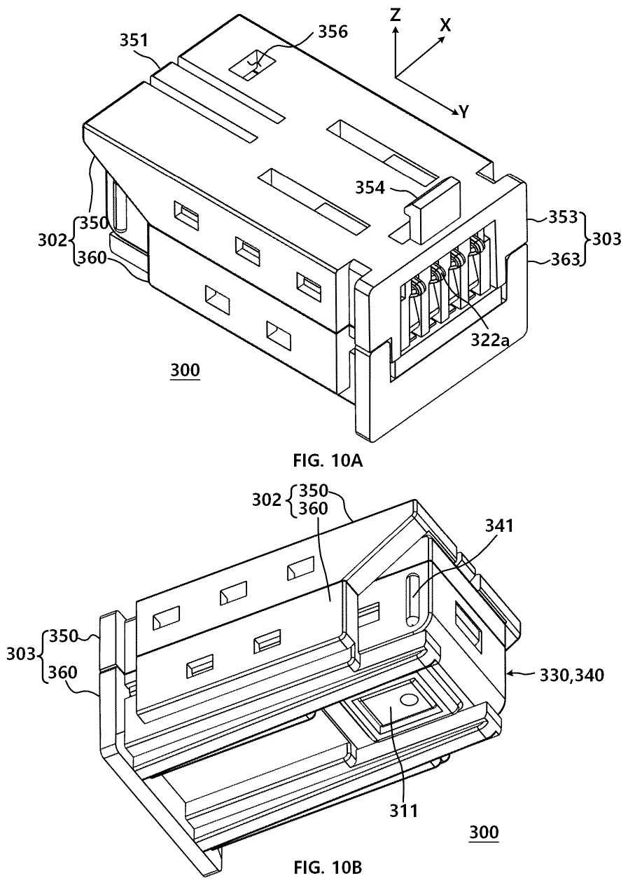

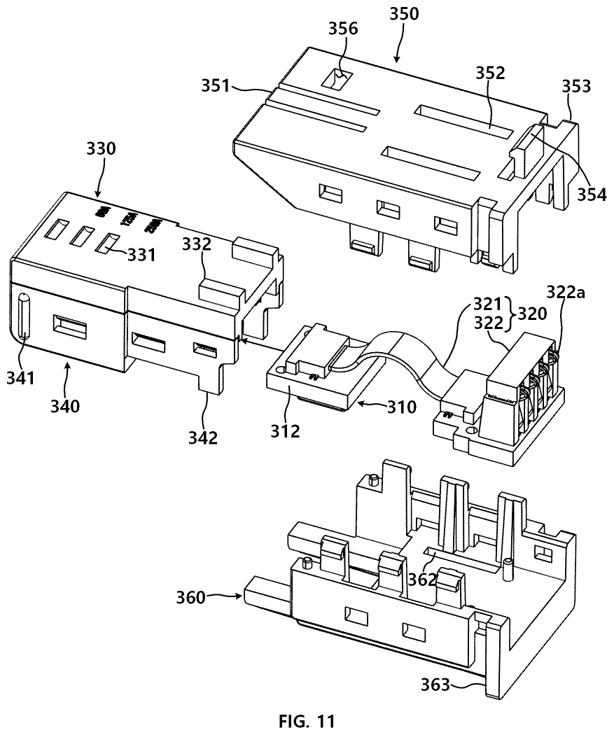

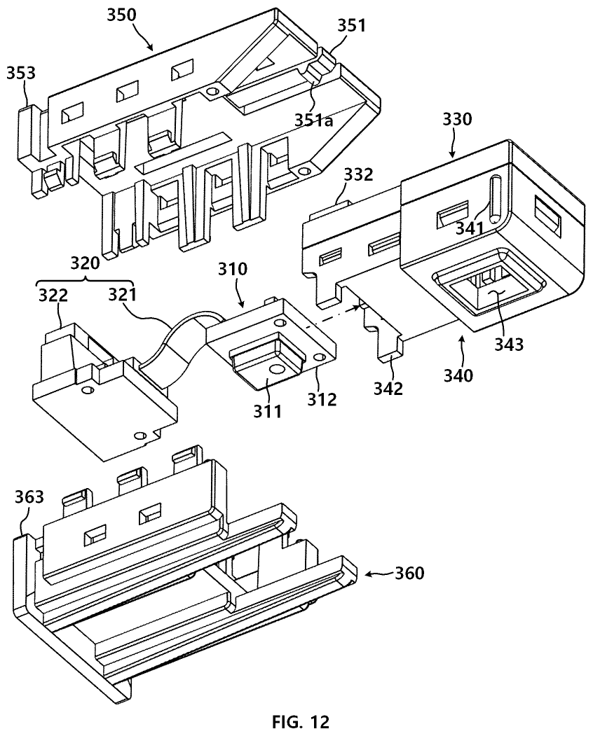

FIG. 10 is a perspective view showing a temperature measurement module according to an embodiment of the present disclosure. FIGS. 11 and 12 are perspective views showing a disassembled temperature measurement module according to an embodiment of the present disclosure.

Since the structures of the first temperature measurement module 300 and the second temperature measurement module 400 are the same, only the “temperature measurement module 300” will be described below. The temperature measurement module 300 is composed of a temperature sensor module 310, a connection means 320; 321 and 322, a sliding module 330 and 340, and a guide case 350 and 360.

The temperature sensor module 310 has a temperature sensor 311 mounted on the lower surface of a PCB substrate 312, and the temperature sensor 311 faces downward through a window 343 of the sliding modules. The temperature sensor module 310 (and the temperature sensor 311) fixedly mounted on the sliding modules may move in a relative position with the main body 10 (upper module 100) by sliding in the transverse direction Y together with the sliding module 330 and 340, and the temperature sensor 311 senses the temperature of the power line toward the bottom and is a non-contact type, for example, an infrared temperature sensor.

The connection means 320; 321 and 322 is a means for electrically connecting between the temperature sensor 311 and the main body connection pins 135 and 136, and is composed of a module connection pin 322 and an FPCB 321.

The FPCB 321 is interposed between the temperature sensor 311 and the module connection pin 322 to form a path for electric signals, and may be flexibly bent even when the temperature sensor 311 and the sliding module 330 and 340 moves in position. The module connection pin 322 is configured with a plurality of spring pins 322a on the side facing the main body 10 and elastically connects one-to-one with the spring pins configured in the main body connection pins 135 and 136 to transmit an electric signal.

The sliding module 330 and 340 is equipped with the temperature sensor 311 and has the window 343 on the lower surface thereof that allows the passage of sensing light. A lens may be provided on the window 343 or between the window 343 and the temperature sensor 311. The lens may be used to focus the sensing light, narrowing the angle (range) of the temperature sensor 311, and accurately sensing only the power line. The sliding module is provided with a first guide protrusion 342 facing downward at the bottom thereof and a second guide protrusion 332 facing upward at the top thereof. In addition, a grip protrusion 341 is formed at the end of the sliding module so that a user can easily hold the sliding module with his/her hand.

The guide case 350 and 360 guides the sliding of the sliding module and is configured to include an upper guide case 350 and a lower guide case 360. The sliding module is mounted between the upper guide case 350 and the lower guide case 360 and configured to be able to slide in the transverse direction (Y direction).

The second guide protrusion 332 of the sliding module is seated in a second guide groove 352 that penetrates the upper surface of the upper guide case 350, so that the sliding module may move in a straight line within a set range, whereas the first guide protrusion 342 of the sliding module is seated in a first guide groove 362 that penetrates the lower surface of the lower guide case 360, so that the sliding module may move in a straight line within a set range.

The guide case 350 and 360 is configured with a flange 303:353 and 363 that extends in the vertical direction around the module connection pin 322. The flange 303 extends in the vertical direction (Z direction) with the same thickness and is provided with a groove extending in the vertical direction (Z direction) on the inside thereof in contact with the flange.

A trench 143a and 143b that matches the flange 303: 353 and 363 is formed in the upper housing 100 of the main body 10 around the main body connection pins 135 and 136, and the lower part of the trench 143a and 143b has an open entrance and the upper part thereof is closed. Thus, the temperature measurement module may be mounted by sliding the flange 303 from the bottom to the top of the open trench 143a and 143b and fitting the flange 303 into the trench. A hook 354 is provided on the upper part of the main body of the upper case 350, and when the flange 353 and 363 is fully inserted into the trench, the hook 354 is secured in a hook groove 144a and 144b of the upper housing 140, thereby preventing the temperature sensor module from falling downward.

On the upper surface of the sliding module, a plurality of micro grooves 331 is formed in the transverse direction (Y direction). In addition, on the upper surface of the sliding module, a plurality of characters indicating the specifications of the MCCB are printed or engraved next to the plurality of micro grooves 331, and the same number of characters as the number of micro grooves 331 are formed. For example, the characters are engraved as 60A, 125A, and 250A.

A cantilever 351 is provided on the upper part of the guide case, and the cantilever 351 also extends in the transverse direction (Y direction), and a protrusion 351a that is settled on one of the micro grooves 331 is formed on the lower part of the front end of the cantilever. When the user adjusts the position of the sliding module, the protrusion 351a of the cantilever 351 will be positioned on one of the micro grooves 331.

On the upper part of the guide case, a confirmation window 356 through which one of the characters is exposed is formed and for example, one of 60A, 125A and 250A is visible through the confirmation window 356 depending on which micro groove 331 the protrusion 351a is seated.

According to the temperature measurement module according to an embodiment of the present disclosure, since the position of the temperature sensor 311 extending from the main body 10 may be adjusted, the temperature of a power line may be sensed by adapting to various standards of power line spacing (MCCB of various standards).

Furthermore, according to the temperature measurement module according to an embodiment of the present disclosure, it is easy to set the position of the temperature sensor 311 according to the specifications of an MCCB and ensure that the temperature sensor 311 is located exactly above a power line.

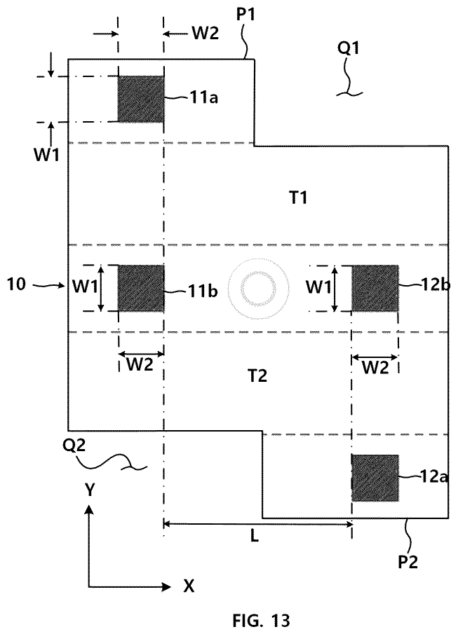

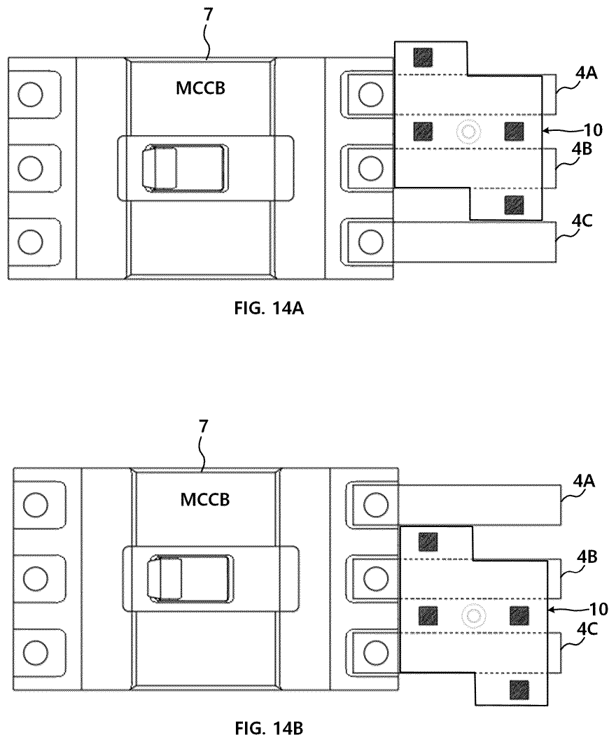

FIG. 13 is a view schematically showing a split-type measurement device according to an embodiment of the present disclosure. FIG. 14 is a view schematically showing a state in which a split-type measurement device according to an embodiment of the present disclosure is mounted on three-phase, three-wire power lines. FIG. 15A is a view schematically showing a state in which a split-type measurement device according to an embodiment of the present disclosure is mounted on two single-phase power lines, and FIG. 15B is a view schematically showing a state in which a split-type measurement device according to an embodiment of the present disclosure is mounted on a three-phase, four-wire power line.

The split-type measurement device measures the current of the first power line (4A in FIGS. 14A and 4B in FIG. 14B) using the first annular core consisting of the first upper core 111 and the first lower core 211, and measures the current of the second power line (4B in FIGS. 14A and 4B in FIG. 14C) using the second annular core consisting of the second upper core 122 and the second lower core 221.

A pair of first contact areas 11a and 11b where the first upper core 111 and the first lower core 211 contact each other, and a pair of second contact areas 12a and 12b where the second upper core 122 and the second lower core 221 contact each other are characterized in that the pair of first contact areas 11a and 11b and the pair of second contact areas 12a and 12b are arranged to be spaced apart from each other in the extension direction (X direction) in which the first power line and the second power line extend.

The pair of first contact areas 11a and 11b includes a 1-1 contact area 11a close to a first side and a 1-2 contact area 11b on the inside (i.e., center), and the pair of first contact areas formed on the same annular core are naturally at the same position in the extension direction (X direction). The pair of second contact areas 12a and 12b includes a 2-1 contact area 12a close to a second side and a 2-2 contact area 12b on the inside (i.e., center), and the pair of second contact areas formed on the same annular core are naturally at the same position in the extension direction (X direction).

In addition, preferably, the 1-2 contact area 11b and the 2-2 contact area 12b are at the same position in the transverse direction (Y direction). As can be seen with reference to FIG. 7, the 1-2 contact area 11b and the 2-2 contact area 12b at the same position in the transverse direction (Y direction) facilitate the design of the insertion part 151 and optimize the horizontal width of the device.

As shown in FIG. 13, the first contact area and the second contact area are sufficiently spaced apart by a distance L in the extension direction, and the split-type measurement device of the present disclosure may realize such spaced arrangement very easily.

In the split-type measurement device according to an embodiment of the present disclosure, the first annular core and the second annular core are characterized in that the first annular core and the second annular core are arranged to be spaced apart from each other in the extension direction (X direction) in which the first power line and the second power line extend.

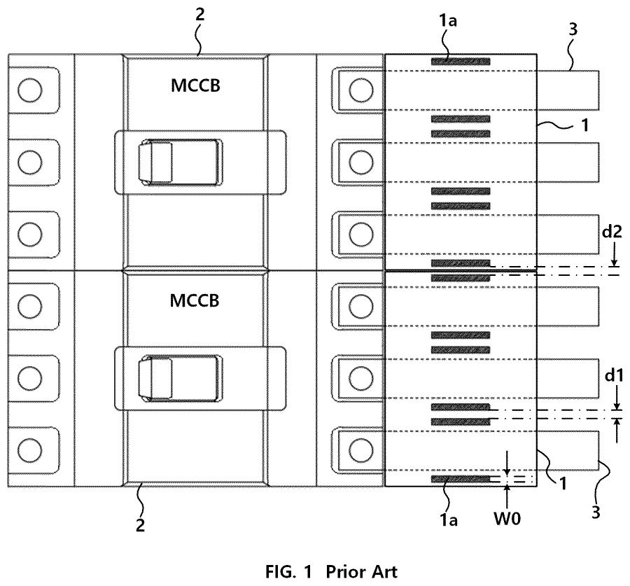

As shown in FIG. 1, according to the conventional split-type measurement device, the three annular cores are not separated at all in the extension direction (X direction) and are arranged in the same position in the extension direction (X direction).

According to the split-type measurement device of the present disclosure, it is easy to arrange contact areas of cores so that the contact areas are sufficiently spaced apart from each other and are not adjacent to each other, which may minimize interference between contact areas and interference with power lines, thereby increasing measurement precision significantly compared to conventional split-type measurement devices. Therefore, it is possible to overcome the limitations in measurement precision of conventional split-type measurement devices.

According to the split-type measurement device of the present disclosure, the pair of first contact areas 11a and 11b and the pair of second contact areas 12a and 12b are square-shaped areas, and it is preferable that a width W1 in the transverse direction perpendicular to the extension direction be greater than 0.5 times but less than 2 times a width W2 in the extension direction, and more preferably, the width W1 in the transverse direction is equal to the width W2 in the extension direction.

In the split-type measurement device according to an embodiment of the present disclosure, the distance L between the pair of first contact areas and the pair of second contact areas, which are separated from each other in the extension direction, is set to be at least 3.4 times larger than the width W1 in the transverse direction perpendicular to the extension direction of the first contact areas and the second contact areas.

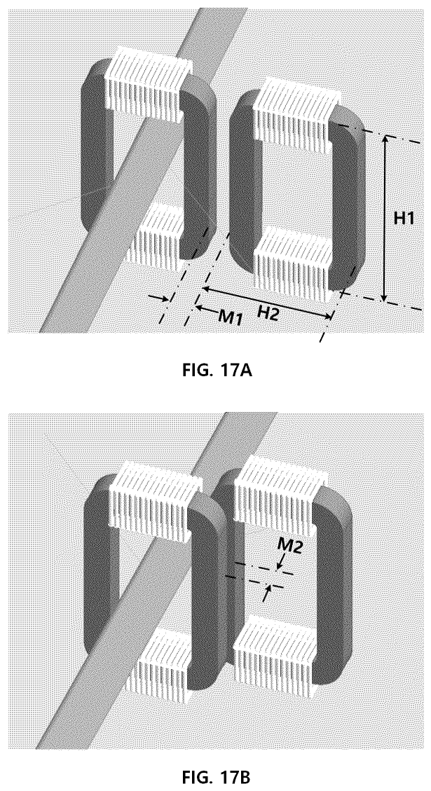

FIG. 17 is a diagram showing a simulation situation. FIG. 17A shows that two cores (hence CTs) are spaced horizontally, similar to the conventional case, and FIG. 17B shows that two cores (hence CTs) are spaced apart in an extension direction as in an embodiment of the present disclosure.

The current flowing in a power line (busbar) is 60 A, a separation distance M1 between cores (and therefore the separation distance between contact areas) in the transverse direction in FIG. 17A is 5 mm, a separation distance M2 between cores (and therefore the separation distance between contact areas) in the extension direction in FIG. 17B is 5 mm, the cross-sectional size of the core and contact area is 6×6 mm, a height H1 of the core is 51.3 mm, a width H2 of the core is 31.0 mm, the number of turns of the winding is 1500 turns, and the diameter of the winding is 0.16 mm.

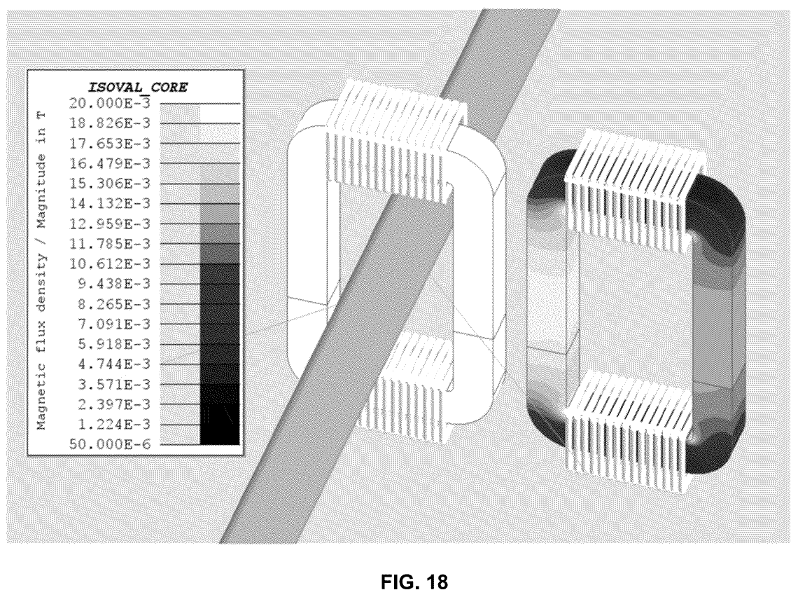

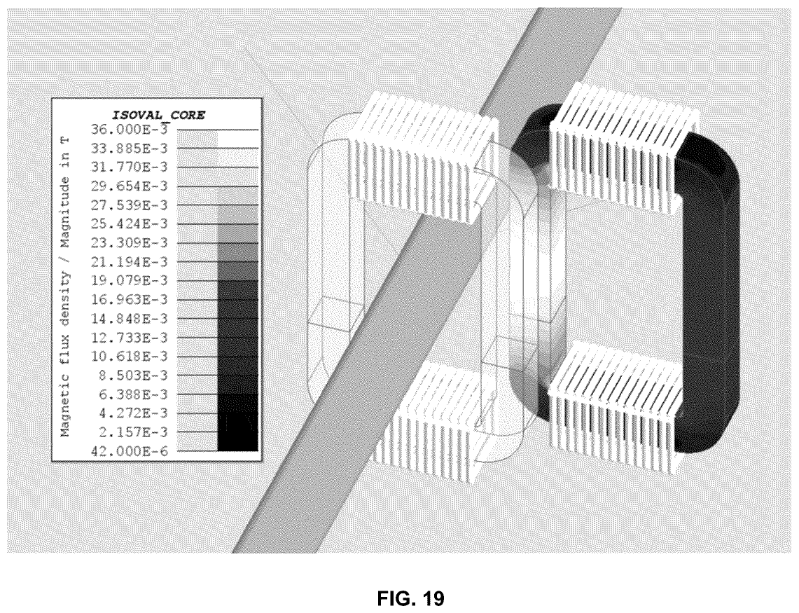

FIGS. 18 and 19 are a visual representation of the magnetic flux density (peak value) in adjacent cores (CTs), with FIG. 18 being according to the arrangement (separation in transverse direction) of FIG. 17A, and FIG. 19 being according to the arrangement (separation in extension direction) of FIG. 17B.

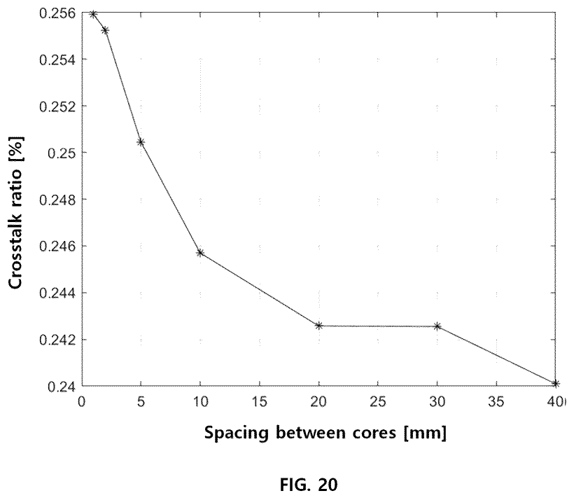

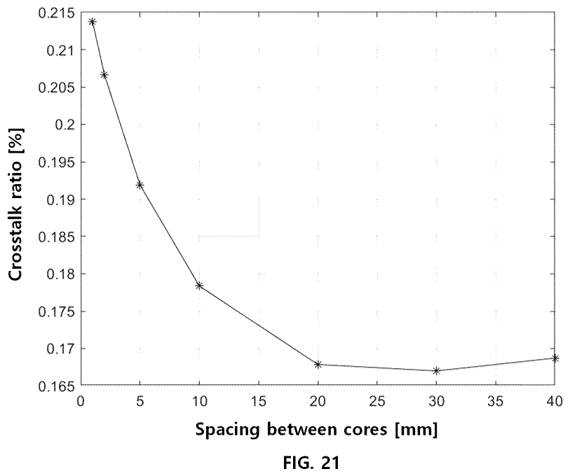

FIGS. 20 and 21 are graphs showing the crosstalk ratio according to a separation distance between cores (CTs), with FIG. 20 being according to the arrangement (separation in transverse direction) of FIG. 17A, and FIG. 21 being according to the arrangement (separation in extension direction) of FIG. 17B.

It can be seen that the crosstalk ratio is lower when the two cores are arranged in the extended direction (front to back) than when the two cores are arranged horizontally when the separation distance between the cores is the same. The crosstalk ratio of the extension arrangement is lower than that of the transversal arrangement at all spacings of 5 mm, 10 mm, 20 mm, 30 mm, and 40 mm, showing the superiority of the arrangement in the extension direction. The crosstalk ratio is lower when two CTs are positioned front to back than when they are positioned next to each other at the same CT spacing. When two CTs are positioned in the direction of progression (front to back), the crosstalk ratio is very low, at approximately 0.165 to 0.17%, when the spacing between the CTs is 20 mm or more.

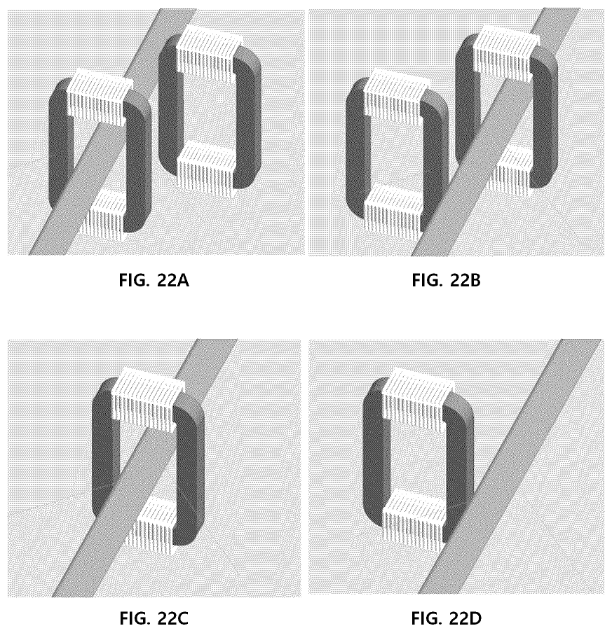

FIG. 22 is a diagram showing a simulation situation performed to determine a separation distance with little influence of crosstalk. FIGS. 22A and 22B show a pair of cores (CT) arranged in the extension direction, with a power line penetrating the left core (CT) in FIG. 22A and a power line penetrating the right core (CT) in FIG. 22B. FIGS. 22C and 22D are configured with only one core (CT). FIG. 22C shows a simulation situation where a power line penetrates the core (CT), and FIG. 22D shows a simulation situation where a power line is located in a space without the core (CT).

In the simulation, the current flowing through the power line (busbar) is 60 A, and other conditions are the same as those in FIG. 17.

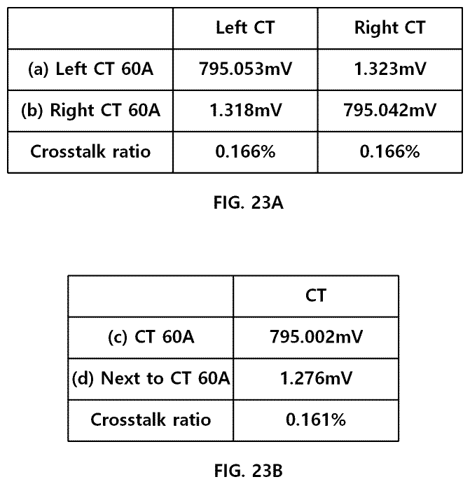

FIG. 23 is a table showing the output voltage and crosstalk ratio. The table in FIG. 23A shows the output voltage and crosstalk ratio obtained from the arrangements in FIGS. 22A and 22B, and the table in 23B shows the output voltage and crosstalk ratio obtained from the arrangements in FIGS. 22C and 22D.

In the case of excluding one CT, the crosstalk ratio is 0.161%, which is a situation where there is no influence from adjacent CTs. However, when the two CTs are separated, the crosstalk ratio is 0.1668, and according to the simulation results in FIG. 21, the crosstalk ratio is lower than 0.17% at 20 mm or more. Then, it can be seen that adjacent CTs are hardly affected by crosstalk when the spacing between the two CTs is at least 20 mm. When two cores are arranged in the extension direction, the adjacent cores are almost free from crosstalk when the spacing between the cores is 20 mm or more.

As shown in FIG. 1, in the conventional split-type measurement device, the width of the contact area in the transverse direction (see W0 in FIG. 1) is inevitably narrow, and thus, when combining the upper module and the lower module, even a slight misalignment between the upper core and the lower core can cause a significant reduction in the contact area, which is problematic.

In the conventional split-type measurement device, two contact areas had to be placed together within the spacing (spacing in transverse direction) between two power lines, but according to the split-type measurement device of the present disclosure, only one contact area needs to be placed within the same spacing, so that the horizontal width of a contact area may be significantly increased.

Therefore, according to the split-type measurement device of the present disclosure, it is easy to increase the horizontal width of a contact area, and there is an advantage of significantly preventing a decrease in the area of the contact area even if the alignment between the upper core and the lower core is misaligned.

As shown in FIG. 14, in a three-phase, three-wire power line, the split-type measurement device (main body) of the present disclosure is applied to two adjacent power lines, and current measurement is performed using the first annular core and the second annular core, respectively, thereby performing current measurement for the three-phase, three-wire power line.

The single split-type measurement device proposed in the present disclosure is capable of measuring the current of a 3 pole MCCB (power line connected to a 3 pole MCCB), and since the sum of the three-phase current is zero even if one phase is not measured, three-phase current measurement may calculate one phase with two phases, eliminating the hardware that measures the remaining phase. Depending on the ease of MCCB configuration, the measurement method shown in FIG. 14A or the measurement method shown in FIG. 14B may be selected and configured.

As shown in FIG. 15A, in two pairs of single-phase power lines connected to two MCCBs, by performing current measurements for two neighboring power lines using the first annular core and the second annular core included in a single split-type measurement device, current measurements for two pairs of single-phase power lines may be performed simultaneously.

In order to measure current in a single-phase MCCB configuration of the same capacity in series, one split-type measurement device may measure the current of one circuit (power line) of each MCCB to handle two single-phase MCCBs, which has the advantage of lowering the unit cost of panel production.

As shown in FIG. 15B, by using the split-type measurement device of the present disclosure, for a three-phase four-wire MCCB and power lines, the first main body 10A may perform current measurements for two of the four power lines, and the second main body 10B may perform current measurements for the remaining two of the four power lines.

In a three-phase, four-wire system, because the current of all four circuits (power lines) needs to be measured independently, measurement devices used for the three-phase, three-wire system cannot be used. Therefore, previously, products for measuring the three-phase, four-wire system had to be manufactured and supplied separately. However, according to the split-type measurement device proposed in the present disclosure, split-type measurement devices applicable to single-phase and three-phase three-wire circuits are used as they are, but there is an advantage in that two split-type measurement devices may be used to respond to three-phase four-wire configurations.

The main body 10 in which the upper module and the lower module are combined is characterized by having a shape of [symbol] or [symbol] with protruding and depressed portions on opposite sides (transverse direction) when viewed from above. In the main body 10 in which the upper module and the lower module are combined, a protruding portion P1 (see FIG. 13) and a depressed portion Q1 are formed in succession on a first side in the transverse direction, and a protruding portion P2 and a depressed portion Q2 are formed in succession on a second side in the transverse direction opposite to the first side, but the depressed portion Q2 on the second side is formed on the opposite side of the protruding portion P1 on the first side, and the protruding portion P2 on the second side is formed on the opposite side of the depressed portion Q1 on the first side.

In addition, as in the example of FIG. 15B, when two main bodies 10A and 10B are placed next to each other, the protruding portion of the second main body is received in the depressed portion of the first main body, and the protruding portion of the first main body is received in the depressed portion of the second main body. A part of the first annular core is positioned inside the protruding portion P1 of the first side, and a part of the second annular core is positioned inside the protruding portion P2 of the second side.

According to the split-type measurement device of the present disclosure, a protruding portion and a depressed portion are formed on the side in the transverse direction, and each protruding portion is configured to align with the depressed portion on the opposite side. Therefore, in situations such as when applying to a three-phase four-wire system or when split-type measurement devices need to be placed in succession, multiple split-type measurement devices may be easily applied.

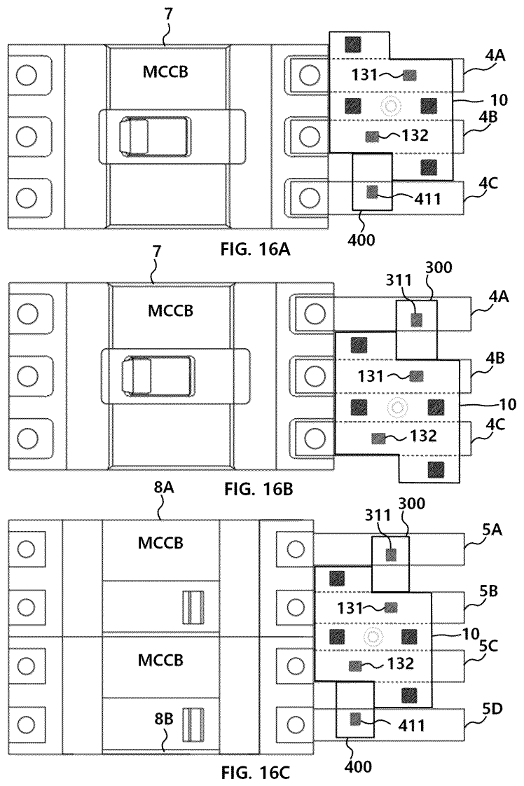

FIG. 16 is a view schematically showing a state in which a temperature measurement module is mounted on a main body of a split-type measurement device according to an embodiment of the present disclosure, with FIGS. 16A and 16B showing different examples of mounting the temperature measurement module on a three-phase, three-wire power line, and FIG. 16C showing an example of mounting the temperature measurement module on two pairs of single-phase power lines.

The first temperature measurement module 300 may be mounted (coupled) on the first side of the main body 10, and the second temperature measurement module 400 may be mounted (coupled) on the second side.

As shown in FIG. 16A, the temperature of power line 4C among the three-phase power lines that do not penetrate the main body 10 may be measured using a temperature sensor 411 of the temperature measurement module 400 separately mounted on the second side, or as shown in FIG. 16B, the temperature of power line 4A among the three-phase power lines that do not penetrate the main body 10 may be measured using a temperature sensor 311 of the temperature measurement module 300 separately mounted on the first side.

As shown in FIG. 16C, among the two pairs of single-phase power lines, the temperature of power line 5A of the two power lines on the outside that do not penetrate the main body 10 is measured using a temperature sensor 311 of the temperature measurement module 300 mounted on the first side, and the temperature of power line 5D of the two power lines on the outside that do not penetrate the main body 10 is measured using a temperature sensor 411 of the temperature measurement module 400 mounted on the second side.

According to the split-type measurement device of the present disclosure, since a user may configure the temperature measurement module in a detachable manner, the temperature may be sensed even for an adjacent power line that does not penetrate the main body, and in an application such as that shown in FIG. 15B, the same main body may be applied even in applications where the main body is placed one after another by removing the temperature measuring module.

What is claimed is:

1. A split-type measurement device comprising:
a first annular core configured to form a closed magnetic circuit around a first power line and consisting of a first upper core and a first lower core; and
a second annular core configured to form a closed magnetic circuit around a second power line and consisting of a second upper core and a second lower core,
wherein an upper module including an upper housing accommodating the first upper core and the second upper core and a lower module including a lower housing accommodating the first lower core and the second lower core may be combined and separated,
an electric current in the first power line is measured using the first annular core, and an electric current in the second power line is measured using the second annular core, and
the first annular core and the second annular core are arranged to be spaced apart from each other in an extension direction, which is a direction in which the first power line and the second power line extend.

2. A split-type measurement device comprising:
a first annular core configured to form a closed magnetic circuit around a first power line and consisting of a first upper core and a first lower core; and
a second annular core configured to form a closed magnetic circuit around a second power line and consisting of a second upper core and a second lower core,
wherein an upper module including an upper housing accommodating the first upper core and the second upper core and a lower module including a lower housing accommodating the first lower core and the second lower core may be combined and separated,
an electric current in the first power line is measured using the first annular core, and an electric current in the second power line is measured using the second annular core, and
a pair of first contact areas where the first upper core and the first lower core contact each other and a pair of second contact areas where the second upper core and the second lower core contact each other core are arranged to be spaced apart from each other in an extension direction, which is a direction in which the first power line and the second power line extend.

3. The device of claim 2, wherein the pair of first contact areas and the pair of second contact areas are square-shaped areas, and a width in a transverse direction perpendicular to the extension direction is greater than 0.5 times but less than 2 times a width in the extension direction.

4. The device of claim 2, wherein a separation distance (L) between the pair of first contact areas and the pair of second contact areas in the extension direction is greater than 20 mm.

5. The device of claim 2, wherein a main body in which the upper module and the lower module are combined has a shape of [symbol] or [symbol] having protruding parts on opposite sides when viewed from above.

6. The device of claim 2, wherein in a main body in which the upper module and the lower module are combined, a protruding portion and a depressed portion are formed in succession on a first side, and a protruding portion and a depressed portion are formed in succession on a second side opposite the first side, wherein the depressed portion of the second side is formed on an opposite side of the protruding portion of the first side, and the protruding portion of the second side is formed on an opposite side of the depressed portion of the first side.

7. The device of claim 6, wherein when two main bodies are placed adjacent to each other, a protruding portion of a second main body is accommodated in a depressed portion of a first main body, and a protruding portion of the first main body is accommodated in a depressed portion of the second main body.

8. The device of claim 2, wherein at a top of the lower housing, a first cylindrical wall standing upright in a shape of a square cylinder surrounding a 1-1 contact area which is close to a side among the first contact areas, and a second cylindrical wall standing upright in a shape of a square cylinder surrounding a 2-1 contact area which is close to a side among the second contact areas are provided.

9. The device of claim 2, wherein at a top of the lower housing, a third cylindrical wall standing upright in a shape of a square cylinder surrounding a 1-2 contact area which is in a center among the first contact areas and a 2-2 contact area which is in a center among the second contact areas is provided.

10. The device of claim 9, wherein at a bottom of the upper housing, an insertion part inserted and aligned with the third cylindrical wall and installed to stand downwardly is provided,
wherein inside the third cylindrical wall, a key piece is provided to stand in a direction perpendicular to the third cylindrical wall, and the key piece is inserted into a key groove of the insertion part to help match the upper module and the lower module.

11. The device of claim 2, wherein in the upper housing and the lower housing combined with each other, a first line through hole through which the first power line passes and a second line through hole through which the second power line passes are formed, and
the upper module further comprises:
a first temperature sensor stored in the upper housing and disposed above the first line through hole to sense a temperature of the first power line; and
a second temperature sensor stored in the upper housing and disposed above the second line through hole to sense a temperature of the second power line.

12. The device of claim 2, further comprising:
a first temperature measurement module configured to be detachably coupled to the upper module on a first side of the upper module, and to sense a temperature of an adjacent power line that does not penetrate a main body; and
a second temperature measurement module configured to be detachably coupled to the upper module on a second side opposite to the first side of the upper module, and to sense a temperature of an adjacent power line that does not penetrate a main body.

13. The device of claim 12, wherein each of the first temperature measurement module and the second temperature measurement module comprises:
a module connection pin configured to be connected to a main body connection pin of the upper module;
a temperature sensor configured to move a position thereof by sliding in a transverse direction and to sense a temperature of a power line downward; and
an FPCB interposed between the temperature sensor and the module connection pin and configured to form a path for electrical signals.

14. The device of claim 13, further comprising:
a sliding module equipped with the temperature sensor and having a window or a lens on a bottom thereof that allows passage of sensing light; and
a guide case configured to guide a sliding of the sliding module.

15. The device of claim 14, further comprising:
a plurality of micro grooves formed in the transverse direction on an upper surface of the sliding module; and
a cantilever constructed on an upper part of the guide case and extending in the transverse direction, and having a protrusion formed at a lower part of a front end thereof to be seated in one of the micro grooves.

16. The device of claim 1, wherein a main body in which the upper module and the lower module are combined has a shape of [symbol] or [symbol] having protruding parts on opposite sides when viewed from above.

17. The device of claim 1, wherein in a main body in which the upper module and the lower module are combined, a protruding portion and a depressed portion are formed in succession on a first side, and a protruding portion and a depressed portion are formed in succession on a second side opposite the first side, wherein the depressed portion of the second side is formed on an opposite side of the protruding portion of the first side, and the protruding portion of the second side is formed on an opposite side of the depressed portion of the first side.

18. The device of claim 1, wherein in the upper housing and the lower housing combined with each other, a first line through hole through which the first power line passes and a second line through hole through which the second power line passes are formed, and
the upper module further comprises:
a first temperature sensor stored in the upper housing and disposed above the first line through hole to sense a temperature of the first power line; and
a second temperature sensor stored in the upper housing and disposed above the second line through hole to sense a temperature of the second power line.

19. The device of claim 1, further comprising:
a first temperature measurement module configured to be detachably coupled to the upper module on a first side of the upper module, and to sense a temperature of an adjacent power line that does not penetrate a main body; and
a second temperature measurement module configured to be detachably coupled to the upper module on a second side opposite to the first side of the upper module, and to sense a temperature of an adjacent power line that does not penetrate a main body.
